(19) United States
(12) Patent Application Publication
(10) Pub. No.: US 2024/0260191 A1
(43) Pub. Date: Aug. 1, 2024

(54) STACKED POWER DESIGN IN A CARD-BASED COMPUTING DEVICE

(71) Applicant: NVIDIA CORPORATION

(72) Inventors: Sien CHEN, Shenzhen (CN); Xuan WANG, Shenzhen (CN); Ziyi XU, Shenzhen (CN)

(21) Appl. No.: 17/923,193

(22) PCT Filed: Jul. 27, 2022
(86) PCT No.: PCT/CN2022/108237

§ 371 Date: Nov. 3, 2022

(51) Int. Cl. H05K 1/14; H05K 1/02; H05K 7/20

(52) U.S. Cl. CPC H05K 1/144; H05K 1/0203; H05K 7/20154; H05K 2201/041; H05K 2201/10545; H05K 2201/10734

(57) ABSTRACT

According to various embodiments, a processing subsystem includes a first printed circuit board (PCB); a processor mounted directly on a first side of the first PCB; and one or more power components. The one or more power components are coupled to a second side of the first PCB and electrically coupled to the processor, where the first side of the first PCB is opposite to the second side of the first PCB.

### BACKGROUND

### Field of the Various Embodiments

The various embodiments relate generally to computer architecture and electronics and, more specifically, to a stacked power design in a card-based computing device.

### DESCRIPTION OF THE RELATED ART

Many types of computers are designed to incorporate one or more expansion cards that provide the computer with additional capabilities, such as enhanced video or gaming performance, accelerated video capture, the ability to connect to a network, and/or the ability to connect to a musical instrument, to name a few. An expansion card, which also is referred to as an adapter card, an add-on card, or an expansion board, is a card-based processing subsystem that typically includes a printed circuit board (PCB) that is adapted to connect to an expansion slot on the motherboard of a given computer.

To provide the microprocessor(s), memory, and other elements of the chipset of a card-based processing subsystem with the appropriate supply voltage and current, the power components of the card-based processing subsystem are usually mounted directly on the PCB portion of the card-based processing subsystem. For example, large capacitors, inductors, and power MOSFETs (metal-oxide-semiconductor field-effect transistors) are generally mounted adjacent to the processor(s) and memory chips on the PCB portion of the processing subsystem. Power is then delivered from these power components to the microprocessor(s), memory, and other elements of the chipset via a power distribution network that is made up of electrically conductive interconnects formed on the surface of, and within, the layers of the PCB, such as metallic traces, plated vias, and power and ground planes.

One drawback of conventional card-based processing subsystems is that adapting these subsystems to consume more power in order to meet the growing performance demands of compute and gaming applications is proving to be quite difficult. First, to provide increased power to the microprocessor(s), memory, and other elements of the chipset of a higher-performance card-based processing subsystem, an increased number of larger power components have to be mounted on the PCB, which results in those power components being mounted farther away from the microprocessor(s), memory, and other elements of the chipset. The increased distance results in longer current paths, which degrades the overall efficiency of the power distribution network, causes more overall power to be consumed and heat to be generated on the PCB, and increases the signal-to-interference ratio of the processing subsystem. Second, to accommodate the additional larger power components, the size of the PCB oftentimes needs to be increased, which increases the size, complexity, and overall cost of the card-based processing subsystem. Third, effective heat dissipation becomes more difficult as more power components are mounted on the PCB because more heat is generated by the additional power components, but less space is available for a thermal solution to dissipate the additional heat.

As the foregoing illustrates, what is needed in the art are more effective techniques for incorporating power components into card-based processing subsystems.

### SUMMARY

According to various embodiments, a processing subsystem includes: a first printed circuit board (PCB); a processor mounted directly on a first side of the first PCB; and one or more power components that are coupled to a second side of the first PCB and electrically coupled to the processor, wherein the first side of the first PCB is opposite to the second side of the first PCB.

At least one technical advantage of the disclosed design relative to the prior art is that the disclosed design enables the power components of a card-based processing subsystem to be positioned closer to the microprocessor(s), memory, and other elements of the chipset of the processing subsystem. The shorter relative current paths between the power components and the microprocessor(s), memory, and other elements of the chipset increase the overall efficiency of the power distribution network of the card-based processing subsystem, cause less overall power to be consumed, cause less overall heat to be generated, and improve the overall signal-to-interference ratio of the processing subsystem. Further, the printed circuit board of the card-based processing subsystem can be reduced in size, which reduces the size, cost, and complexity of the processing subsystem, and facilitates the inclusion of more efficient thermal solutions in the card-based processing subsystem. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a computer system configured to implement one or more aspects of the various embodiments;

FIG. 2 is a more detailed illustration of the computer system of FIG. 1, according to various embodiments;

FIG. 3 is a more detailed illustration of the card-based processing subsystem of FIG. 2, according to various embodiments;

FIG. 4 is a more detailed illustration of the card-based processing subsystem of FIG. 2, according to various other embodiments;

FIG. 5A is an illustration of a portion of a motherboard that can receive a card-based processing subsystem, according to various embodiments;

FIG. 5B is an illustration of a portion of a motherboard with a card-based processing subsystem installed thereon, according to various embodiments;

FIG. 5C is an illustration of a portion of a motherboard with a card-based processing subsystem installed thereon, according to various other embodiments; and

FIG. 6 is a more detailed illustration of the card-based processing subsystem of FIG. 2, according to various other embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skilled in the art that the inventive concepts may be practiced without one or more of these specific details.

### System Overview

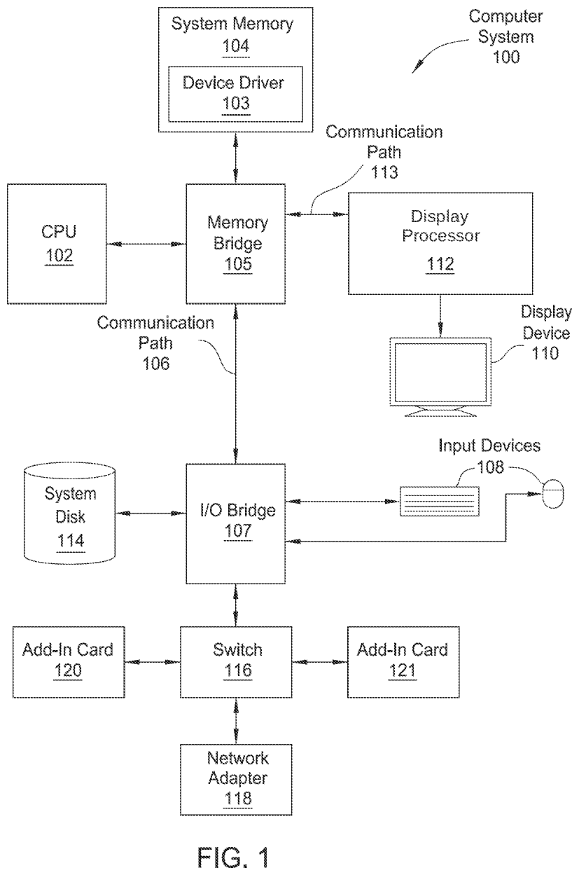

FIG. 1 is a conceptual illustration of a computer system 100 configured to implement one or more aspects of the various embodiments. As shown, system 100 includes a central processing unit (CPU) 102 and a system memory 104 communicating via a bus path that may include a memory bridge 105. CPU 102 includes one or more processing cores, and, in operation, CPU 102 is the master processor of system 100, controlling and coordinating operations of other system components. System memory 104 stores software applications and data for use by CPU 102. CPU 102 runs software applications and optionally an operating system. Memory bridge 105, which may be, e.g., a Northbridge chip, is connected via a bus or other communication path (e.g., a HyperTransport link) to an I/O (input/output) bridge 107. I/O bridge 107, which may be, e.g., a Southbridge chip, receives user input from one or more user input devices 108 (e.g., keyboard, mouse, joystick, digitizer tablets, touch pads, touch screens, still or video cameras, motion sensors, and/or microphones) and forwards the input to CPU 102 via memory bridge 105.

A display processor 112 is coupled to memory bridge 105 via a bus or other communication path (e.g., a PCI Express, Accelerated Graphics Port, or HyperTransport link); in one embodiment display processor 112 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 104.

Display processor 112 periodically delivers pixels to a display device 110 (e.g., a screen or conventional CRT, plasma, OLED, SED or LCD based monitor or television). Additionally, display processor 112 may output pixels to film recorders adapted to reproduce computer generated images on photographic film. Display processor 112 can provide display device 110 with an analog or digital signal. In various embodiments, a graphical user interface is displayed to one or more users via display device 110, and the one or more users can input data into and receive visual output from the graphical user interface.

A system disk 114 is also connected to I/O bridge 107 and may be configured to store content and applications and data for use by CPU 102 and display processor 112. System disk 114 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 116 provides connections between I/O bridge 107 and other components such as a network adapter 118 and various add-in cards 120 and 121. Network adapter 118 allows system 100 to communicate with other systems via an electronic communications network, and may include wired or wireless communication over local area networks and wide area networks such as the Internet.

Other components (not shown), including USB or other port connections, film recording devices, and the like, may also be connected to I/O bridge 107. For example, an audio processor may be used to generate analog or digital audio output from instructions and/or data provided by CPU 102, system memory 104, or system disk 114. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 112 is configured as a processing subsystem that incorporates circuitry optimized for graphics and video processing, including, for example, video output circuitry, and constitutes a graphics processing unit (GPU). In another embodiment, display processor 112 is configured as a processing subsystem that incorporates circuitry optimized for general purpose processing. In yet another embodiment, display processor 112 may be integrated with one or more other system elements, such as the memory bridge 105, CPU 102, and I/O bridge 107 to form a system on chip (SoC). In still further embodiments, display processor 112 is omitted and software executed by CPU 102 performs the functions of display processor 112.

Pixel data can be provided to display processor 112 directly from CPU 102. In some embodiments, instructions and/or data representing a scene are provided to a render farm or a set of server computers, each similar to system 100, via network adapter 118 or system disk 114. The render farm generates one or more rendered images of the scene using the provided instructions and/or data. These rendered images may be stored on computer-readable media in a digital format and optionally returned to system 100 for display. Similarly, stereo image pairs processed by display processor 112 may be output to other systems for display, stored in system disk 114, or stored on computer-readable media in a digital format.

Alternatively, CPU 102 provides display processor 112 with data and/or instructions defining the desired output images, from which display processor 112 generates the pixel data of one or more output images, including characterizing and/or adjusting the offset between stereo image pairs. The data and/or instructions defining the desired output images can be stored in system memory 104 or graphics memory within display processor 112. In an embodiment, display processor 112 includes 3D rendering capabilities for generating pixel data for output images from instructions and data defining the geometry, lighting shading, texturing, motion, and/or camera parameters for a scene. Display processor 112 can further include one or more programmable execution units capable of executing shader programs, tone mapping programs, and the like.

Further, in other embodiments, CPU 102 or display processor 112 may be replaced with or supplemented by any technically feasible form of processing device configured to process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 102, display processor 112, or one or more other processing devices or any combination of these different processors.

CPU 102, render farm, and/or display processor 112 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 100 may or may not include other elements shown in FIG. 1. System memory 104 and/or other memory units or devices in system 100 may include instructions that, when executed, cause the robot or robotic device represented by system 100 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 104 is connected to CPU 102 directly rather than through a bridge, and other devices communicate with system memory 104 via memory bridge 105 and CPU 102. In other alternative topologies display processor 112 is connected to I/O bridge 107 or directly to CPU 102, rather than to memory bridge 105. In still other embodiments, I/O bridge 107 and memory bridge 105 might be integrated into a single chip. The particular components shown herein are optional; for instance, any number of add-in cards or peripheral devices might be supported. In some embodiments, switch 116 is eliminated, and network adapter 118 and add-in cards 120, 121 connect directly to I/O bridge 107.

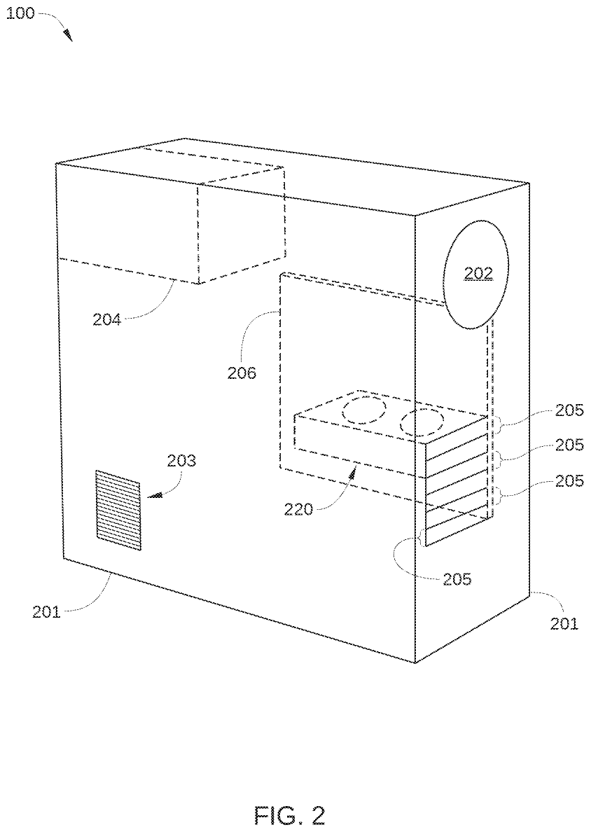

FIG. 2 is a more detailed illustration of computer system 100, according to an embodiment. As shown, computer system 100 includes a chassis 201 (also referred to as a “case” or “housing”) with one or more system cooling fans 202 mounted thereon and one or more cooling inlets 203 formed therein. Cooling fans 202 are configured to draw cooling air into chassis 201, for example via cooling inlets 203, to remove heat generated by various electronic components of computer system 100. Computer system 100 further includes a power supply 204 mounted within chassis 201, a plurality of chassis expansion slots 205 that are typically located on a rear surface of chassis 201, and a motherboard 206 disposed within chassis 201.

Computer system 100 further includes various external connections (omitted for clarity) mounted or disposed on a rear and/or front surface of chassis 201, such as a power connection, Universal Serial Bus (USB) connections, an audio input jack, an audio output jack, one or more video output connections, and/or other connections. In some embodiments, one or more of such external connections are associated with motherboard 206 and/or one or more expansion cards that are coupled to motherboard 206 and installed in a chassis expansion slot 205, such as a card-based processing subsystem 220.

In the embodiment illustrated in FIG. 2, motherboard 206 is configured with a central processing unit (CPU) and one or more card edge connectors, such as peripheral component interconnect express (PCIe) slots, that are each positioned to correspond to a different chassis expansion slot 205. For clarity, the CPU and card edge connectors of motherboard 206 are omitted in FIG. 2. Generally, computer system 100 is configured with one or more expansion cards or other card-based processing subsystems that are each mounted in a different chassis expansion slot 205 and communicatively coupled to motherboard 206 via a corresponding card edge connector. Examples of such card-based processing subsystems include card-based processing subsystems 220, such as wireless adapters, sound cards, graphics cards, network adapter 118, add-in cards 120, 121, or display processor 112 of FIG. 1, and/or the like. In the embodiment illustrated in FIG. 2, a single card-based processing subsystem 220 is coupled to motherboard 206, but in other embodiments, a plurality of card-based processing subsystems 220 may be coupled to motherboard 206.

In some embodiments, computer system 100 further includes one or more peripheral devices (not shown) that are communicatively coupled to motherboard 206 and/or a particular expansion card coupled to motherboard 206. For example, in some embodiments, computer system 100 includes one or more of a keyboard, mouse, joystick, digitizer tablet, touch pad, touch screen, display device, external hard drive, still or video cameras, motion sensors, microphones, and/or the like.

In the embodiment illustrated in FIG. 2, computer system 100 is depicted as a tower-configured desktop computer system. In other embodiments, computer system 100 can have any configuration that can include a card-based processing subsystem, such as a tower server computer system, a blade server computer system, a rack server computer system, a laptop computer, and the like.

### Card-Based Processing Subsystem

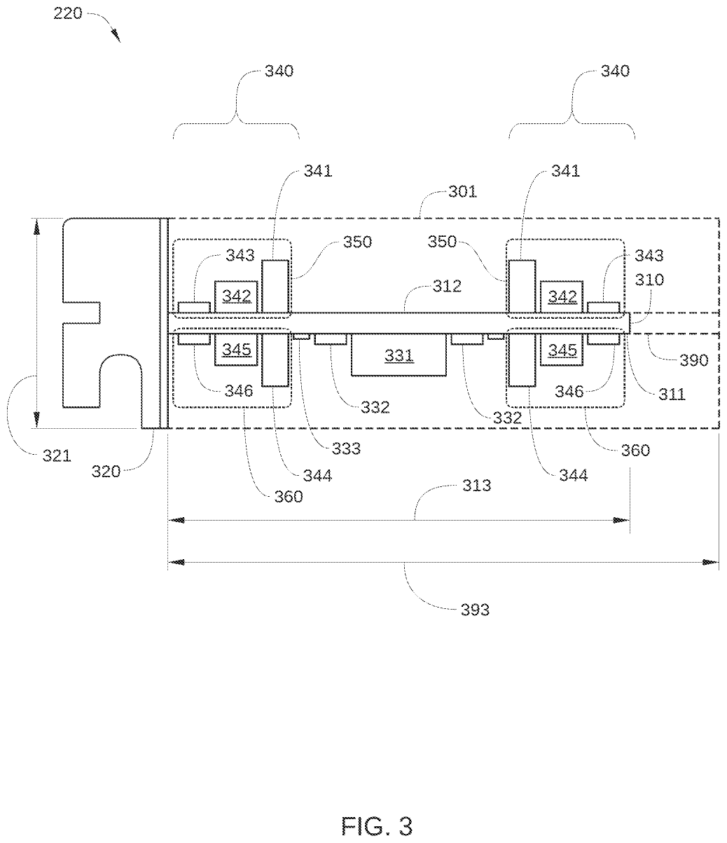

FIG. 3 is a more detailed illustration of card-based processing subsystem 220, according to various embodiments. Specifically, FIG. 3 is a side view of card-based processing subsystem 220, which includes a printed circuit board (PCB) 310 coupled to a backplate bracket 320.

PCB 310 is configured to communicatively couple card-based processing subsystem 220 to a card edge connector, such as a PCIe slot included on motherboard 206 of computer system 100. To that end, PCB 310 includes a plurality of edge connectors (not shown) formed on an edge of PCB 310.

Backplate bracket 320 couples card-based processing subsystem 220 to a surface of a chassis of a computing device. In the embodiment illustrated in FIG. 3, backplate bracket 320 and card-based processing subsystem 220 are configured to have a width of a single chassis expansion slot 205 (shown in FIG. 2), and therefore backplate bracket 320 has a width 321 of about 20 mm. In other embodiments, card-based processing subsystem 220 can be configured to occupy a region proximate motherboard 206 (shown in FIG. 2) that corresponds to two, three, or four chassis expansion slots 205. In such embodiments, backplate bracket 320 can have a width of about 40 mm, 60 mm, or 80 mm, respectively. In some embodiments, card-based processing subsystem 220 also includes a housing that contains most or all components of card-based processing subsystem 220. For clarity, in FIG. 3 only an outline 301 (dashed line) of such a housing is depicted.

Card-based computing processing subsystem 220 further includes a processor 331, one or more memory chips 332, a chipset 333 of one or more integrated circuits, and a plurality of power components 340. In embodiments in which card-based processing subsystem 220 is configured as a graphics card, processor 331 is a graphics processing unit (GPU) and some or all of memory chips 332 are graphics memory chips associated with the GPU. As such, memory chips 332 are mounted as close as practicable to processor 331, to reduce signal latency and improve the signal-to-interference ratio (S/I) of PCB 310.

Power components 340 include electronic devices that are mounted to a PCB and provide processor 331, memory chips 332, and chipset 333 with appropriate supply voltage and current. For example, in some embodiments, power components 340 include one or more capacitors, inductors, voltage controllers, and/or power switching devices that are coupled to a primary side 311 of PCB 310 or a secondary side 312 of PCB 310. In the embodiment illustrated in FIG. 3, power components 340 include capacitors 344, inductors 345, and power switching devices 346 (such as field-effect transistors and/or metal-oxide-semiconductor field-effect transistors) that are mounted on primary side 311 of PCB 310 and capacitors 341, inductors 342, and power switching devices 343 that are mounted on secondary side 312 of PCB 310. In some embodiments, power components 340 include some or all of the elements of a voltage regulator module, or VRM, which performs direct current (DC) to DC conversion to the various operating voltages associated with processor 331, memory chips 332, and/or chipset 333. Thus, in such embodiments, some or all of power components 340 provide a constant DC output voltage and a required current to processor 331, memory chips 332, and/or chipset 333. For example, in some embodiments, power components 340 provide such voltage and current to processor 331, memory chips 332, and/or chipset 333 with a power distribution network (not shown) formed as part of PCB 310. In such embodiments, the power distribution network typically includes electrically conductive interconnects formed on the surfaces of PCB 310 and within the layers of PCB 310, such as metallic traces, plated vias, and power and ground planes.

According to various embodiments, at least one secondary-side set 350 of power components 340 is mounted on secondary side 312 of PCB 310, while processor 331, the one or more memory chips 332, and one or more of integrated circuits 333 are mounted on primary side 311 of PCB 310. In some embodiments, at least one primary-side set 360 of power components 340 is also mounted on primary side 311 of PCB 310. In the embodiment illustrated in FIG. 3, a secondary-side set 350 of power components 340 includes capacitors 341, inductors 342, and power switching devices 343 and a primary-side set 360 of power components 340 includes capacitors 344, inductors 345, and power switching devices 346.

As shown, two secondary-side sets 350 of power components 340 are mounted on a different side of PCB 310 than processor 331, the one or more memory chips 332, integrated circuits 333, and two primary-side sets 360 of power components 340. It is noted that in conventional card-based processing subsystems, all power components are mounted on the primary side of a PCB, along with most or all of the load devices of the card-based processing subsystem (such as the processor, memory chips, and the integrated circuits of the chipset). By contrast, according to various embodiments, two secondary-side sets 350 of power components 340 are mounted on secondary side 312. As shown, the two secondary-side sets 350 of power components 340 are disposed closer to the load devices of card-based processing subsystem 220 (such as processor 331, memory chips 332, and/or integrated circuits 333) than if mounted on primary side 311 of PCB 310, along with the primary-side sets 360 of power components 340. As a result, there is a shorter current path in the power distribution network of card-based processing subsystem 220 between the power components 340 of the secondary-side sets 350 and the load devices of card-based processing subsystem 220. Consequently, the power distribution network of card-based processing subsystem 220 consumes less power, generates less additional heat, and operates with a reduced S/I.

In the embodiment illustrated in FIG. 3, certain power components 340 of a secondary-side set 350 are aligned with similar power components 340 of a primary-side set 360 in a “mirrored” configuration. For example, some or all of capacitors 341 in a secondary-side set 350 are aligned with a corresponding capacitor 344 in a primary-side set 360, some or all of inductors 342 in a secondary-side set 350 are aligned with a corresponding inductor 345 in a primary-side set 360, and/or some or all of power switching devices 343 in a secondary-side set 350 are aligned with a corresponding power switching device 346 in a primary-side set 360. In such embodiments, a capacitor 341 and a capacitor 344 can each be electrically coupled to the same element of the power distribution network of card-based computing processing subsystem 220, an inductor 342 and an inductor 345 can each be electrically coupled to the same element of the power distribution network of card-based computing processing subsystem 220, and/or a power switching device 343 and a power switching device 346 can each be electrically coupled to the same element of the power distribution network of card-based computing processing subsystem 220. In such embodiments, an element of the power distribution network can be a particular power plane formed within PCB 310, a particular ground plane formed within PCB 310, a via formed through PCB 310, and the like. Thus, in such embodiments, the fabrication of PCB 310 can be simplified, the current paths between power components 340 and the load devices of card-based processing subsystem 220 are shortened, and the S/I of card-based processing subsystem 220 improved.

In the embodiment illustrated in FIG. 3, the stacked configuration of a secondary-side set 350 and a primary-side set 360 of power components 340 enables PCB 310 to have a length 313 that is less than the length of a conventional PCB, on which secondary-side sets 350 and primary-side sets 360 of power components 340 are both mounted. For reference, a conventional PCB 390 is shown (dashed lines), on which all power components and load devices are mounted on a single side thereof. As shown, conventional PCB 390 has a length 393 that significantly exceeds length 313 of PCB 310. Because PCB 310 is shorter than the PCB of a conventional card-based processing subsystem, card-based processing subsystem 220 can include an enhanced thermal solution in a region that is not occupied by a full-length PCB. Embodiments of such enhanced thermal solutions are described below.

Card-Based Processing Subsystem with Enhanced Thermal Solution

In card-based processing subsystems, integrated circuits, power components, and the power distribution network can generate significant quantities of heat during operation. This heat needs to be removed from the computing device for the integrated circuits and processing subsystem to operate effectively. For example, a single high-power chip, such as a CPU or GPU, can generate hundreds of watts of heat during operation, and, if this heat is not removed from the computing device, the temperature of the chip can increase to a point where the chip can be permanently damaged. To prevent thermal damage during operation, in addition to implementing conventional cooling systems, many computing devices implement clock-speed throttling when the operating temperature of a processor exceeds a certain threshold. Thus, in these computing devices, the processing speed of the high-power chip is constrained by how effectively heat is removed from the chip.

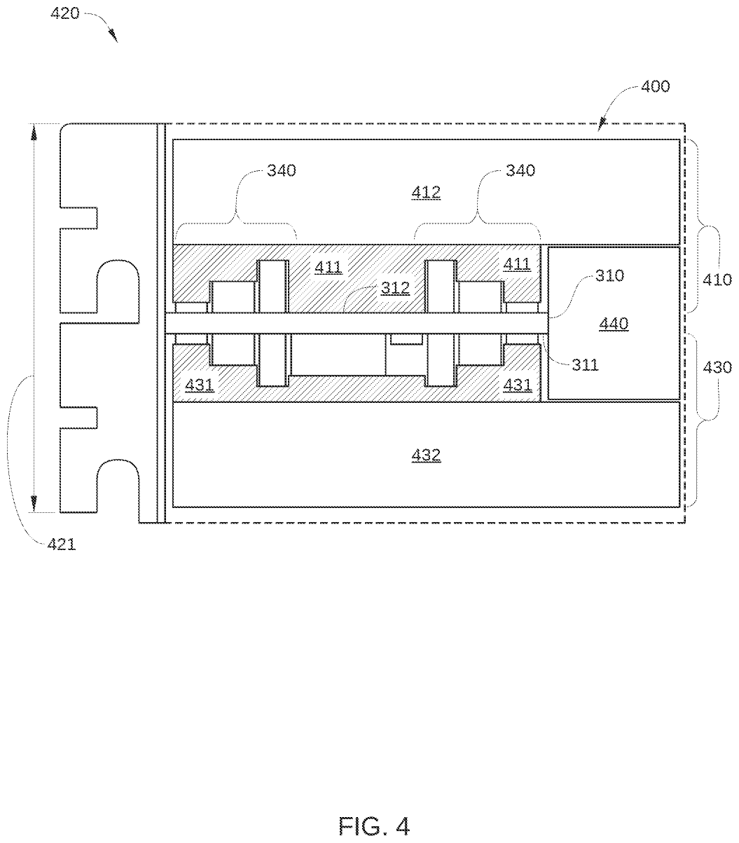

For many card-based processing subsystems, such as a graphics card with a high-power chip or GPU, efficient removal of heat generated by the chip can be hampered by the size limitations of the card-based processing subsystem. For example, to prevent a graphics card that is installed in one of the peripheral component interconnect express (PCIe) slots located on the motherboard of the computing device from blocking most or all of the remaining PCIe slots located on the motherboard, graphics cards are typically limited in thickness to the width of one, two, or occasionally up to three case expansion slots of a computer chassis. That is, all the components of a graphics card, including the PCB on which the GPU is mounted and the various components of the thermal solution, are arranged within an assembly that is limited to a thickness of 20 mm, 40 mm, or 60 mm. According to various embodiments, the stacked configuration of power components in a card-based processing subsystem and the shortened PCB of the card-based processing subsystem enable an enhanced thermal solution to be included in the card-based processing subsystem. Embodiments of such enhanced thermal solutions are described below in conjunction with FIG. 4.

FIG. 4 is a more detailed illustration of a card-based processing subsystem 420, according to various other embodiments. Card-based processing subsystem 420 is similar to card-based processing subsystem 220 of FIG. 2, but further includes an enhanced thermal solution 400. In the embodiment illustrated if FIG. 4, enhanced thermal solution 400 includes a first thermal solution 410, a second thermal solution 430, and a cooling fan 440. As shown, first thermal solution 430 is mounted on and thermally coupled to primary side 311 of PCB 310, and second thermal solution 410 is mounted on and thermally coupled to secondary side 312 of PCB 310. In some embodiments, first thermal solution 410 is oriented substantially parallel to and extends past PCB 310. Alternatively or additionally, in some embodiments, second thermal solution 430 is oriented substantially parallel to and extends past PCB 310.

In some embodiments, first thermal solution 410 includes a thermal transfer plate 411 and a heat transfer device 412. In some embodiments, thermal transfer plate 411 (cross-hatched) is a stiffening member that provides card-based processing subsystem 420 with structural rigidity. In addition, in some embodiments, thermal transfer plate 411 is configured to contact one or more of power components 340, so that heat generated by power components 340 can be distributed over a large heat-distribution surface of thermal transfer plate 411. In such embodiments, the heat-distribution surface contacts a surface of heat transfer device 412, so that heat absorbed by thermal transfer plate 411 is transferred to heat transfer device 412. Heat transfer device 412 can be any technically feasible apparatus for transferring heat from card-based processing subsystem 420, for example via cooling fan 440. For example, in some embodiments, heat transfer device 412 includes one or more of a vapor chamber, a heat pipe, a cold plate, or a heat sink with cooling fins.

In some embodiments, second thermal solution 430 includes a thermal transfer plate 431 and a heat transfer device 432. In some embodiments, thermal transfer plate 431 (cross-hatched) is similar to thermal transfer plate 411 in configuration and operation, and heat transfer device 432 is similar to heat transfer device 412 in configuration and operation.

Cooling fan 440 forces cooling air through or across heat transfer device 412 and heat transfer device 432. In the embodiment illustrated in FIG. 4, cooling fan 440 is disposed in a region of card-based processing subsystem 420 that does not include PCB 310. That is, because PCB 310 can be shortened, there is more space within card-based processing subsystem 420 for cooling fan 440. As a result, greater airflow with cooling fan 440 can be achieved, which improves heat transfer from card-based processing subsystem 420. In addition, in the embodiment illustrated in FIG. 4, cooling fan 440 is oriented to force cooling air through or across heat transfer device 412 and heat transfer device 432. In other embodiments, heat transfer device 412 and heat transfer device 432 may each include one or more cooling fans (not shown).

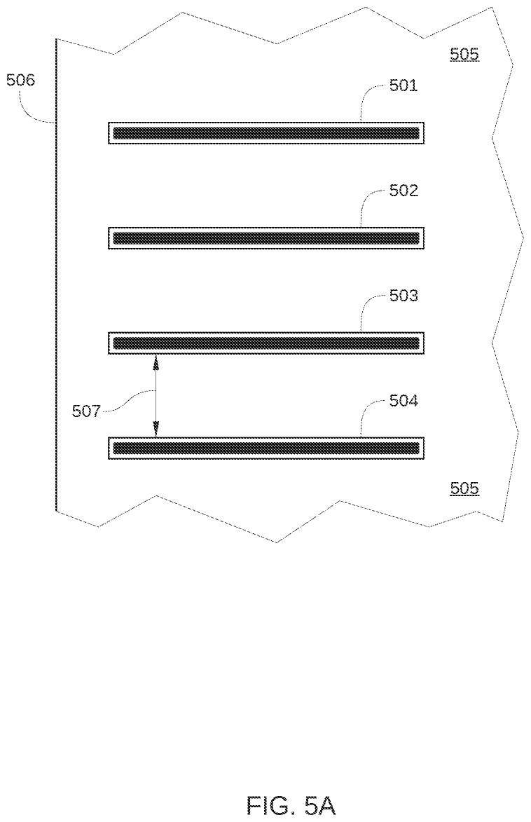

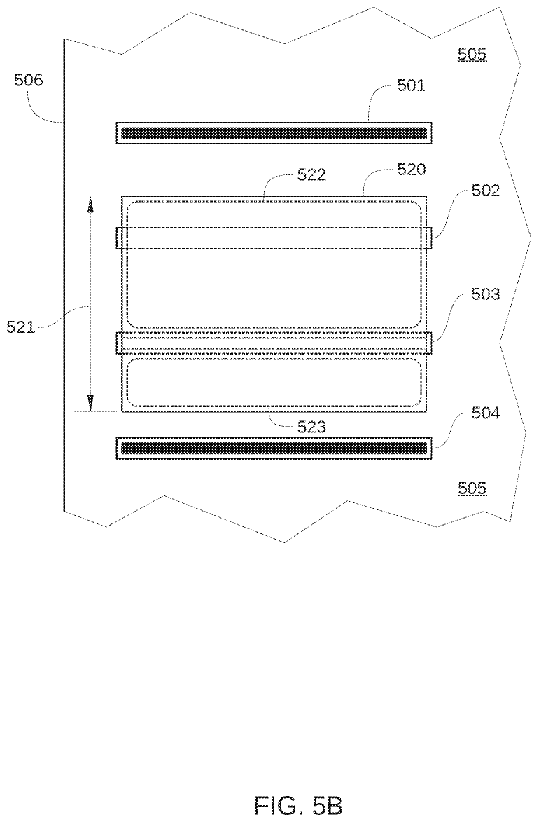

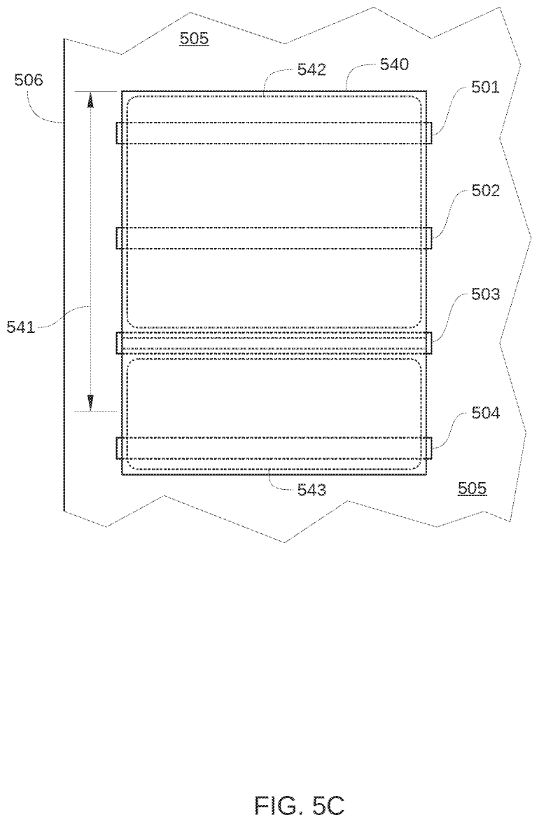

In the embodiment illustrated in FIG. 4, card-based processing subsystem 420 is configured with a width 421 that corresponds to two chassis expansion slots of a motherboard. In other embodiments, a card-based processing subsystem can have a width that corresponds to three more chassis expansion slots. Such embodiments are described below in conjunction with FIGS. 5A-5C.

Positioning of Card-Based Processing Subsystem within Computing Device

FIG. 5A is an illustration of a portion of a motherboard 505 that can receive a card-based processing subsystem, according to various embodiments. Motherboard 505 can be disposed within, for example, a chassis of the computer system 100 of FIGS. 1 and 2. As shown, motherboard 505 includes multiple expansion card slots 501-504, such as PCIe slots, which are disposed proximate a panel 506 of a computer system chassis. Generally, expansion card slots 501-504 are separated by a distance 507 that limits a width of card-based processing subsystems installed on motherboard 505.

FIG. 5B is an illustration of portion of motherboard 505 with a card-based processing subsystem 520 installed thereon, according to various embodiments. As shown, card-based processing subsystem 520 has a width 521 that is sufficient to prevent the use of an adjacent PCIe slot. For example, card-based processing subsystem 520 may include a first thermal solution 522 on a first side of a PCB (not shown) and a second thermal solution 523 on a second side of the PCB, causing card-based processing subsystem 520 to extend a significant distance from the PCB in two directions. Thus, in the embodiment illustrated in FIG. 5B, card-based processing subsystem 520 is installed in PCIe slot 503, but also blocks PCIe slot 502. However, PCIe slot 501 and PCIe slot 504 are still available for the installation of other card-based processing subsystems. In the embodiment illustrated in FIG. 5B, card-based processing subsystem 520 utilizes space adjacent to motherboard 505 for one or more enhanced thermal solutions that can substantially improve heat transfer from the power components and the load devices of card-based processing subsystem 520.

FIG. 5C is an illustration of a portion of motherboard 505 with a card-based processing subsystem 540 installed thereon, according to various embodiments. As shown, card-based processing subsystem 540 has a width 541 that is sufficient to prevent the use of one adjacent PCIe slot on one side and two PCIe slots on another side. For example, card-based processing subsystem 540 may include a first thermal solution 543 on a first side of a PCB (not shown) that causes card-based processing subsystem 540 to block PCIe slot 504 and a second larger thermal solution 542 on a second side of the PCB that causes card-based processing subsystem 540 to block PCIe slot 501 and PCIe slot 502. Thus, in the embodiment illustrated in FIG. 5C, card-based processing subsystem 540 is installed in PCIe slot 503, and utilizes space adjacent to motherboard 505 for one or more enhanced thermal solutions. The one or more enhanced thermal solutions can substantially improve heat transfer from the power components and the load devices of card-based processing subsystem 540.

Card-Based Processing Subsystem Formed with Multiple PCBs

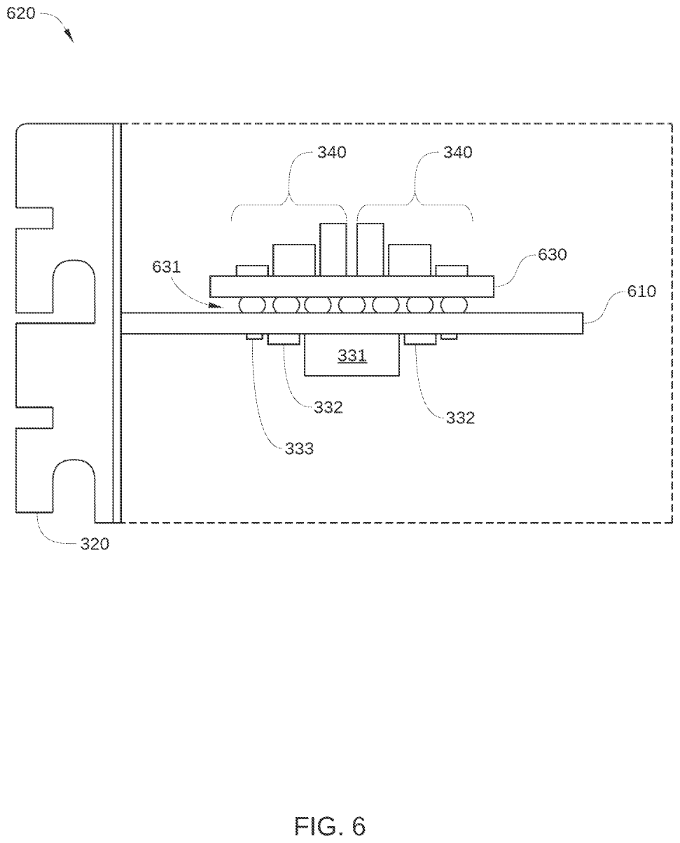

In some embodiments, a card-based processing subsystem includes a stacked configuration of power components that includes multiple PCBs. In such embodiments, the load devices of the card-based processing subsystem are mounted on a first PCB and some or all of the power components of the card-based processing subsystem are mounted on a second PCB. One such embodiment is described below in conjunction with FIG. 6.

FIG. 6 is a more detailed illustration of card-based processing subsystem 620, according to various other embodiments. Specifically, FIG. 6 is a side view of card-based processing subsystem 220, which includes a first PCB 610 that is coupled to backplate bracket 320 and a second PCB 630 that is coupled to and/or mounted on first PCB 610. For example, in some embodiments, second PCB 630 is communicatively coupled to first PCB 610 with a plurality of solder balls 631, pin connections (not shown), or other electrically conductive connectors. In the embodiment illustrated in FIG. 6, power components 340 are mounted on second PCB 630, while the load devices of card-based processing subsystem 620, such as processor 331, memory chips 332, and/or integrated circuits 333, are mounted on first PCB 610. Thus, power components 340 are coupled to first PCB 610 via second PCB 630. As a result, PCB 610 is significantly shorter than the PCB of a conventional card-based processing subsystem, and the power distribution network of card-based processing subsystem 620 includes shorter current paths.

In the embodiment illustrated in FIG. 6, first PCB 610 generally carries high-speed signals between processor 331, memory chips 332, and/or integrated circuits 333. By contrast, there are typically no high-speed signals carried by second PCB 630. This is because no integrated circuits or load devices that transmit or receive high-speed signals are mounted on second PCB 630, and there is no need to route such signals through second PCB 630. Instead, in the embodiment illustrated in FIG. 6, only power components 340 are mounted on second PCB 630. In such embodiments, second PCB 630 can be formed from different materials than first PCB 610. For example, to reduce conduction and dielectric losses associated with high-speed signals, first PCB 610 may include mid-loss or low-loss laminate material compared to the laminate material included in second PCB 630. As a result, PCB 630 can be formed from a significantly lower-cost PCB material than first PCB 610. Examples of mid-loss or low-loss laminate materials suitable for use in first PCB 610 include: IT150-GS, EM528K, NPG-170D.

In sum, the various embodiments shown and provided herein set forth techniques for incorporating power components in card-based processing subsystems, such as graphics cards. Specifically, in the embodiments, the power components of a card-based processing subsystem are arranged in a stacked configuration, in which the processor, memory, and other load devices of the card-based processing subsystem are mounted on one side of a PCB and at least a portion of the power devices of the card-based processing subsystem are coupled to the opposite side of the PCB. In some embodiments, some or all of the power devices are mounted on a second PCB that is coupled to the PCB on which the load devices are mounted.

At least one technical advantage of the disclosed design relative to the prior art is that the disclosed design enables the power components of a card-based processing subsystem to be positioned closer to the microprocessor(s), memory, and other elements of the chipset of the processing subsystem. The shorter relative current paths between the power components and the microprocessor(s), memory, and other elements of the chipset increase the overall efficiency of the power distribution network of the card-based processing subsystem, cause less overall power to be consumed, cause less overall heat to be generated, and improve the overall signal-to-interference ratio of the processing subsystem. Further, the printed circuit board of the card-based processing subsystem can be reduced in size, which reduces the size, cost, and complexity of the processing subsystem, and facilitates the inclusion of more efficient thermal solutions in the card-based processing subsystem. These technical advantages provide one or more technological advancements over prior art approaches.
1. In some embodiments, a processing subsystem comprises: a first printed circuit board (PCB); a processor mounted directly on a first side of the first PCB; and one or more power components that are coupled to a second side of the first PCB and electrically coupled to the processor, wherein the first side of the first PCB is opposite to the second side of the first PCB.
2. The processing subsystem of clause 1, further comprising a first thermal solution coupled to the processor and a second thermal solution coupled to the one or more power components.
3. The processing subsystem of clauses 1 or 2, further comprising a cooling fan that is oriented to blow cooling air across the first thermal solution and the second thermal solution.
4. The processing subsystem of any of clauses 1-3, wherein the first thermal solution includes at least one of cold plate, a heat sink, a cooling fan, a heat pipe, or a vapor chamber.
5. The processing subsystem of any of clauses 1-4, wherein the first thermal solution is oriented parallel to and extends past the first PCB.
6. The processing subsystem of any of clauses 1-5, further comprising one or more other power components that are mounted directly on the first side of the first PCB.
7. The processing subsystem of any of clauses 1-6, wherein the one or more power components are mounted directly on the second side of the first PCB and are arranged on the second side of the first PCB to mirror the one or more other power components.
8. The processing subsystem of any of clauses 1-7, wherein a first power component included in the one or more power components is aligned with a second power component included in the one or more other power components, and each of the first power component and the second power component is electrically coupled to a first power plane or a first ground plane.
9. The processing subsystem of any of clauses 1-8, wherein a first power component included in the one or more power components is aligned with a second power component included in the one or more other power components, and each of the first power component and the second power component is electrically coupled to a first via formed through the first PCB.
10. The processing subsystem of any of clauses 1-9, wherein the one or more power components are mounted directly on the second side of the first PCB.
11. The processing subsystem of any of clauses 1-10, wherein the one or more power components include at least one of a capacitor, an inductor, a voltage controller, or a power switching device.
12. The processing subsystem of any of clauses 1-11, further comprising a second PCB that is coupled to the first PCB, wherein the one or more power components are mounted directly on a first side of the second PCB.
13. The processing subsystem of any of clauses 1-12, wherein a second side of the second PCB is directly attached to the first side of the first PCB.
14. In some embodiments, a computer system, comprises: a chassis; a power supply disposed within the chassis; a motherboard disposed that is disposed within the chassis and is electrically coupled to the power supply; and a processing subsystem that is disposed within the chassis and is communicatively coupled to the motherboard, the processing subsystem including: a first printed circuit board (PCB); a processor mounted directly on a first side of the first PCB; and one or more power components that are coupled to a second side of the first PCB and electrically coupled to the processor, wherein the first side of the first PCB is opposite to the second side of the first PCB.
15. The computer subsystem of clause 14, further comprising a first thermal solution coupled to the processor and a second thermal solution coupled to the one or more power components.
16. The computer subsystem of clauses 14 or 15, further comprising a cooling fan that is oriented to blow cooling air across the first thermal solution and the second thermal solution.
17. The computer subsystem of any of clauses 14-16, wherein the first thermal solution includes at least one of cold plate, a heat sink, a cooling fan, a heat pipe, or a vapor chamber.
18. The computer subsystem of any of clauses 14-17, wherein the first thermal solution is oriented parallel to and extends past the first PCB.
19. The computer subsystem of any of clauses 14-18, further comprising one or more other power components that are mounted directly on the first side of the first PCB.
20. The computer subsystem of any of clauses 14-19, wherein the one or more power components are mounted directly on the second side of the first PCB and are arranged on the second side of the first PCB to mirror the one or more other power components.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

While the preceding is directed to embodiments of the present disclosure, other and further embodiments of the disclosure may be devised without departing from the basic scope thereof, and the scope thereof is determined by the claims that follow.

What is claimed is:

1. A processing subsystem, comprising:
a first printed circuit board (PCB);
a processor mounted directly on a first side of the first PCB; and
one or more power components that are coupled to a second side of the first PCB and electrically coupled to the processor,
wherein the first side of the first PCB is opposite to the second side of the first PCB.

2. The processing subsystem of claim 1, further comprising a first thermal solution coupled to the processor and a second thermal solution coupled to the one or more power components.

3. The processing subsystem of claim 2, further comprising a cooling fan that is oriented to blow cooling air across the first thermal solution and the second thermal solution.

4. The processing subsystem of claim 2, wherein the first thermal solution includes at least one of cold plate, a heat sink, a cooling fan, a heat pipe, or a vapor chamber.

5. The processing subsystem of claim 1, wherein the first thermal solution is oriented parallel to and extends past the first PCB.

6. The processing subsystem of claim 1, further comprising one or more other power components that are mounted directly on the first side of the first PCB.

7. The processing subsystem of claim 6, wherein the one or more power components are mounted directly on the second side of the first PCB and are arranged on the second side of the first PCB to mirror the one or more other power components.

8. The processing subsystem of claim 6, wherein a first power component included in the one or more power components is aligned with a second power component included in the one or more other power components, and each of the first power component and the second power component is electrically coupled to a first power plane or a first ground plane.

9. The processing subsystem of claim 6, wherein a first power component included in the one or more power components is aligned with a second power component included in the one or more other power components, and each of the first power component and the second power component is electrically coupled to a first via formed through the first PCB.

10. The processing subsystem of claim 1, wherein the one or more power components are mounted directly on the second side of the first PCB.

11. The processing subsystem of claim 1, wherein the one or more power components include at least one of a capacitor, an inductor, a voltage controller, or a power switching device.

12. The processing subsystem of claim 1, further comprising a second PCB that is coupled to the first PCB, wherein the one or more power components are mounted directly on a first side of the second PCB.

13. The processing subsystem of claim 12, wherein a second side of the second PCB is directly attached to the first side of the first PCB.

14. A computer system, comprising:
a chassis;
a power supply disposed within the chassis;
a motherboard disposed that is disposed within the chassis and is electrically coupled to the power supply; and
a processing subsystem that is disposed within the chassis and is communicatively coupled to the motherboard, the processing subsystem including:
a first printed circuit board (PCB);
a processor mounted directly on a first side of the first PCB; and
one or more power components that are coupled to a second side of the first PCB and electrically coupled to the processor,
wherein the first side of the first PCB is opposite to the second side of the first PCB.

15. The computer subsystem of claim 1, further comprising a first thermal solution coupled to the processor and a second thermal solution coupled to the one or more power components.

16. The computer subsystem of claim 15, further comprising a cooling fan that is oriented to blow cooling air across the first thermal solution and the second thermal solution.

17. The computer subsystem of claim 15, wherein the first thermal solution includes at least one of cold plate, a heat sink, a cooling fan, a heat pipe, or a vapor chamber.

18. The computer subsystem of claim 1, wherein the first thermal solution is oriented parallel to and extends past the first PCB.

19. The computer subsystem of claim 1, further comprising one or more other power components that are mounted directly on the first side of the first PCB.

20. The computer subsystem of claim 18, wherein the one or more power components are mounted directly on the second side of the first PCB and are arranged on the second side of the first PCB to mirror the one or more other power components.
